(19) United States
(12) Patent Application Publication
(10) Pub. No.: US 2014/0151895 A1
(43) Pub. Date: Jun. 5, 2014

(54) DIE HAVING THROUGH-SUBSTRATE VIAS WITH DEFORMATION PROTECTED TIPS

(71) Applicant: TEXAS INSTRUMENTS INCORPORATED, Dallas, TX (US)

(72) Inventors: JEFFREY ALAN WEST, DALLAS, TX (US); RAJESH TIWARI, PLANO, TX (US); MARGARET SIMMONS-MATTHEWS, RICHARDSON, TX (US)

(73) Assignee: TEXAS INSTRUMENTS INCORPORATED, Dallas, TX (US)

(21) Appl. No.: 13/705,314

(22) Filed: Dec. 5, 2012

(51) Int. Cl. H01L 23/48; H01L 21/768

(52) U.S. Cl. CPC H01L 23/481; H01L 21/76898
USPC 257/774; 438/667

(57) ABSTRACT

A through-substrate via (TSV) die includes a substrate with a top side semiconductor surface having active circuitry therein including a plurality of transistors functionally connected and a bottom side surface. A plurality of TSVs extend from the top side semiconductor surface to TSV tips which protrude from the bottom side surface and include an inner metal core of electrically conductive filler material surrounded by a dielectric liner that forms an outer edge for the TSVs. A tip deformation protecting layer of inorganic dielectric material is on the bottom side surface lateral to the TSV tips. An elastic modulus of the inorganic dielectric material is greater than (>) an elastic modulus of the electrically conductive filler material. A second dielectric layer including a polymer is on the tip deformation protecting layer.

### FIELD

Disclosed embodiments generally relate to the fabrication of integrated circuit (IC) devices and, more specifically, to fabricating through-substrate via (TSV) die having protruding TSV tips, and semiconductor assembly involving thermo-compression bonding of such TSV die.

### BACKGROUND

As known in the art of integrated circuits (ICs), through-substrate vias (referred to herein as TSVs), which are commonly referred to as through-silicon vias in the case of silicon substrates, are vertical electrical connections that extend the full thickness of the substrate. TSVs extend from one of the electrically conductive levels formed on the top side surface of the semiconductor die (e.g., contact level or one of the back end of the line (BEOL) metal interconnect levels) to at least its bottom side surface. Such semiconductor die are referred to herein as “TSV die.”

TSVs are generally framed by a dielectric liner which are then filled to form a metal core with copper or another electrically conductive TSV filler material to provide a low resistance vertical electrical connection through the full thickness of the substrate. A diffusion barrier layer comprising a metal (e.g., refractory metal) formed on the dielectric liner frames the TSV and protects against escape of the TSV filler material into the semiconductor in the case of highly mobile metal TSV filler materials, such as copper.

The vertical electrical paths provided by TSVs are shortened in length relative to conventional wire bonding technology, generally leading to significantly faster device operation. In one arrangement, the TSVs terminate on the bottom side of the TSV die as protruding TSV tips, such as protruding a distance of 3 μm to 15 μm from the bottom side substrate (e.g., silicon) surface. To form the protruding tips, the TSV die are commonly thinned in wafer form while bonded to a carrier wafer which provides mechanical support to expose the TSVs and to form the TSV tips, such as to a die thickness of 25 μm to 100 μm, using a process generally including backgrinding. The TSV die can be bonded face-up or face-down, and can be bonded to from both of its sides to enable formation of stacked (3 dimensional) devices.

TSV die are commonly assembled using thermo-compression (TC) bonding. TC bonding is a technique involving the simultaneous application of a predetermined amount of heat and pressure at the interface between two mating surfaces so as to form a fusion type bond therebetween. TC bonding can be used to form solder comprising joints, or other metal joints.

### SUMMARY

Disclosed embodiments recognize thermo-compression (TC) bonding an integrated circuit (IC) die that includes through substrate vias (a “TSV die”) having TSV tips that protrude from a bottom side of the substrate to a workpiece (e.g., semiconductor device) involves a significant force exerted on the limited cross-section area of the TSV tip. The resulting high pressure (force/area) can lead to deformation of the TSV tip, which can result in the rupture of both the dielectric liner and the thin metal barrier layer (if present) leading to electrical leakage (e.g., shorting) between the TSV and the surrounding substrate (e.g., Si), which can cause immediate device failure. Even in the case that the TSV and surrounding substrates are designed to be at the same electrical potential (e.g., ground) during operation of the integrated circuit (IC), TSV tip deformation during TC bonding can also result in problems. For example, out-diffusion of the electrically conductive filler material of the inner metal core (e.g., copper) of the TSV into the surrounding substrate (e.g., a Si substrate) can cause degraded minority carrier lifetimes in the semiconductor, and lead to problems such as increased junction leakage or a shift in metal-oxide-semiconductor (MOS) transistor threshold voltage.

One embodiment comprises a TSV die including a substrate with a top side semiconductor surface having active circuitry therein including a plurality of transistors functionally connected and a bottom side surface. A plurality of TSVs extend from the top side semiconductor surface to TSV tips which protrude from the bottom side surface and include an inner metal core of an electrically conductive filler material surrounded by a dielectric liner that forms an outer edge for the TSVs. A tip deformation protecting layer of an inorganic dielectric material is on the bottom side surface lateral to the TSV tips, and there is a second dielectric layer comprising a polymer on the tip deformation protecting layer.

Disclosed embodiments solve this TSV tip deformation-induced liner damage problem by using a dielectric layer on the bottom side of the substrate having an elastic modulus greater than (>) that of the TSV inner metal core metal, referred to herein as a “tip deformation protecting dielectric layer”. The tip deformation protecting dielectric layer can be directly on the bottom side of the substrate, where “directly on” as used herein means being within 50 Angstroms of the bottom side of the substrate (e.g., on a “native” oxide layer of 10 to 20 Angstroms in the case of a silicon substrate). In another embodiment, an inorganic dielectric layer can be between the bottom side of the substrate and the tip deformation protecting dielectric layer. Disclosed tip deformation protecting dielectric layers reduce the deformation of the TSV tip in the direction normal to the TSV length axis, such as during TC bonding, and also vertically offset the closest deformation zone (created during TC bonding) further from the bottom side substrate surface (by a distance dependent on its thickness) to reduce the opportunity for electrical shorting between the inner metal core of the TSV and the substrate.

### BRIEF DESCRIPTION OF THE DRAWINGS

Reference will now be made to the accompanying drawings, which are not necessarily drawn to scale, wherein:

FIG. 1 is a flow chart showing steps in an example method of forming TSV die including a plurality of TSVs having TSV tips including a disclosed tip deformation protecting dielectric layer on the bottom side of the substrate, according to an example embodiment.

FIGS. 2A-F show successive simplified cross sectional depictions corresponding to steps in an example method of fabricating TSV die including a plurality of TSVs having TSV tips including a disclosed tip deformation protecting dielectric layer on the bottom side of the substrate, according to an example embodiment.

FIG. 3 is a simplified cross sectional depiction of an example TSV die having a plurality of TSVs having TSV tips including a disclosed tip deformation protecting dielectric layer on the bottom side of the substrate, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

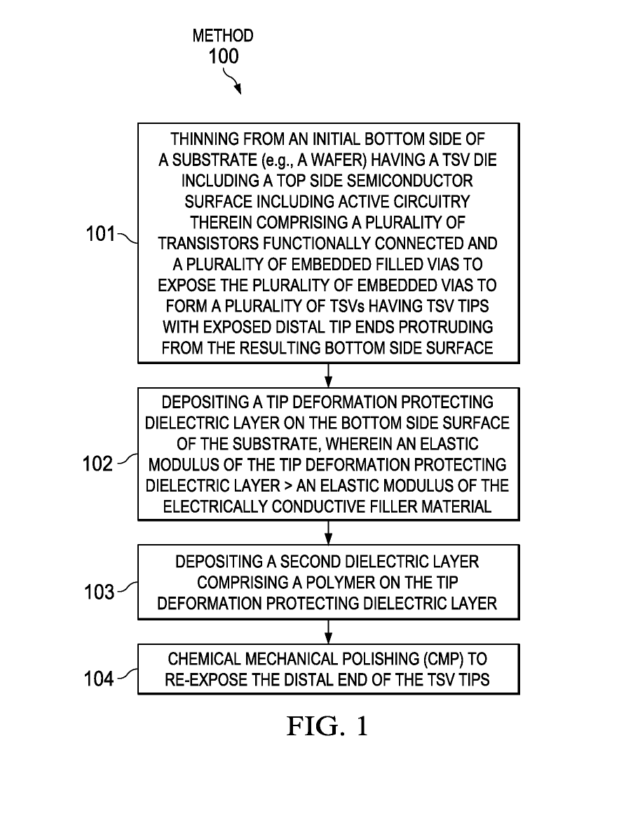

FIG. 1 is a flow chart showing steps in an example method 100 of forming TSV die having a plurality of TSV tips with and a TSV tip deformation protecting dielectric layer having an elastic modulus greater than that of the TSV core metal on the bottom side of the substrate lateral to the TSV tips, according to an example embodiment. As noted above, a disclosed tip deformation protecting dielectric layer reduces the deformation of the TSV tip in the direction normal to the TSV (length) axis, such as during TC bonding, and also vertically offsets the closest deformation zone (created during TC bonding) further from the bottom side substrate surface (by a distance dependent on its thickness) to eliminate the opportunity for electrical shorting between the TSV and the substrate.

Step 101 comprises thinning from an initial bottom side of a substrate (e.g., a wafer) having TSV die including a top side semiconductor surface having active circuitry therein comprising a plurality of transistors functionally connected and a plurality of embedded filled vias to expose the plurality of embedded vias to form a plurality TSVs having TSV tips with exposed distal tip ends protruding from the resulting bottom side surface. The top side semiconductor surface can comprise silicon, silicon germanium, or other materials.

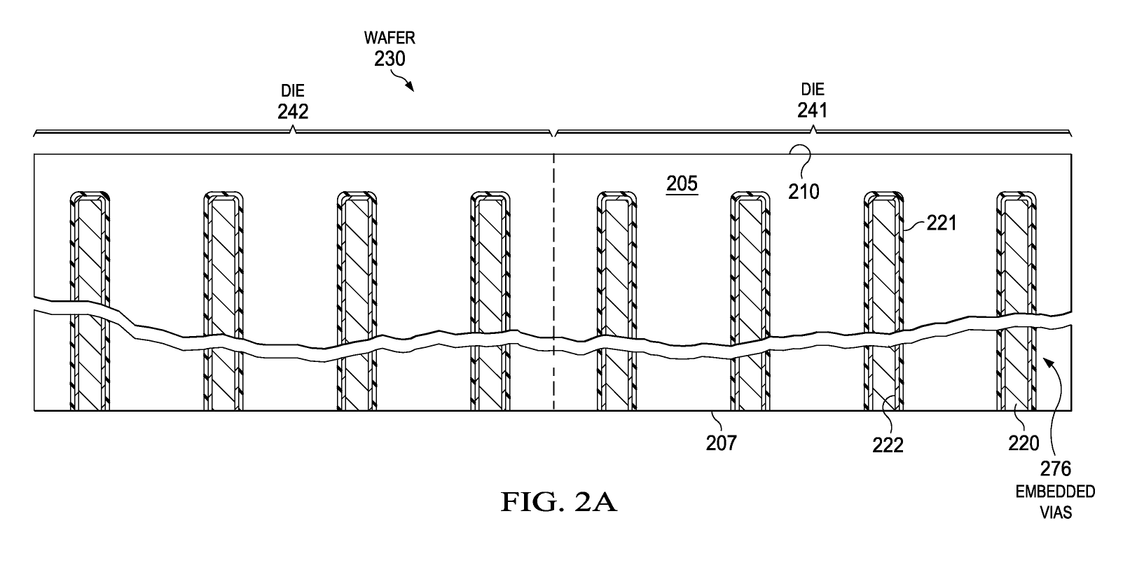

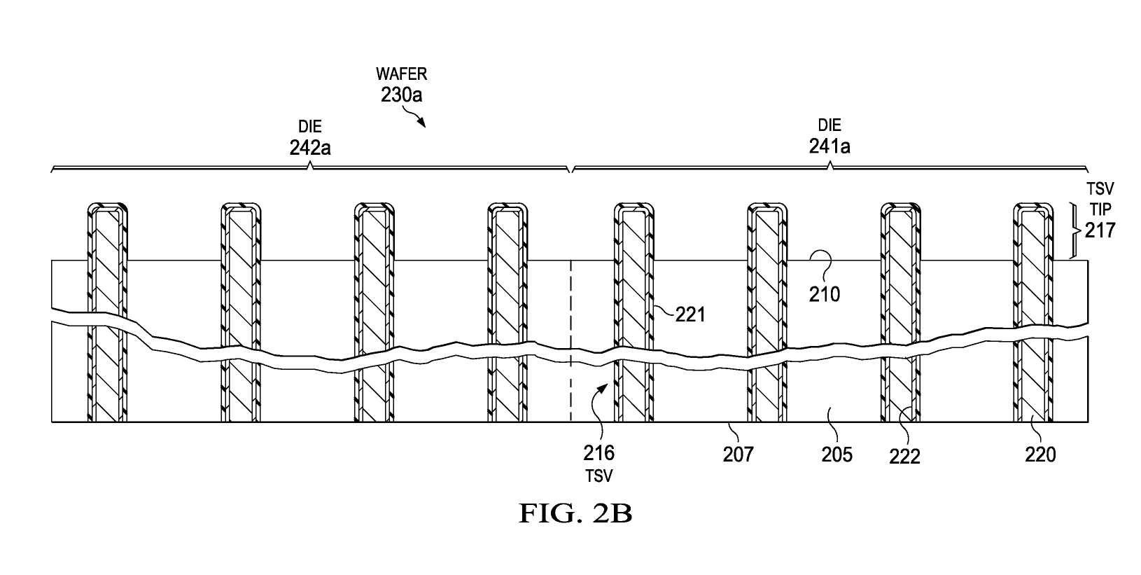

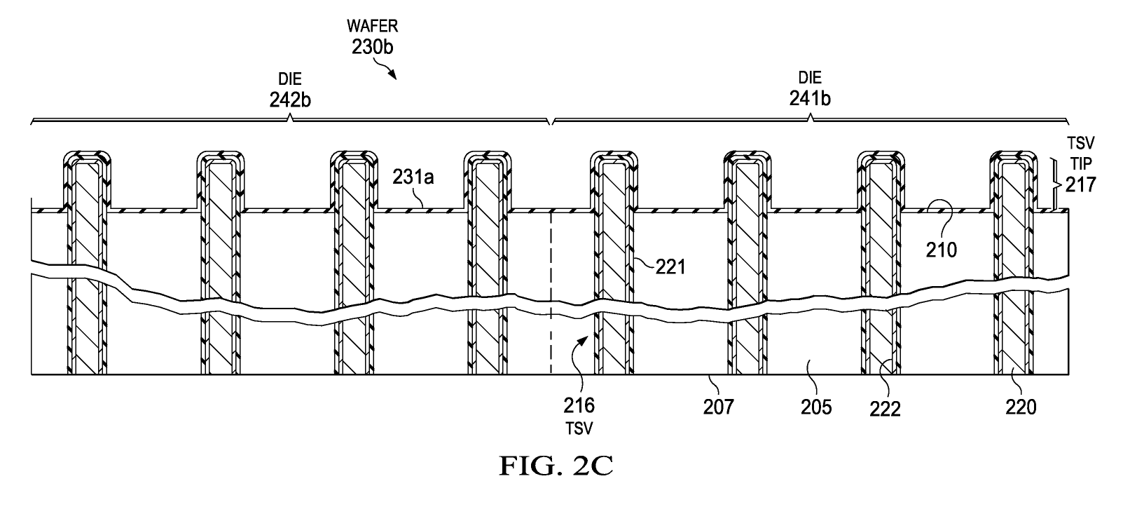

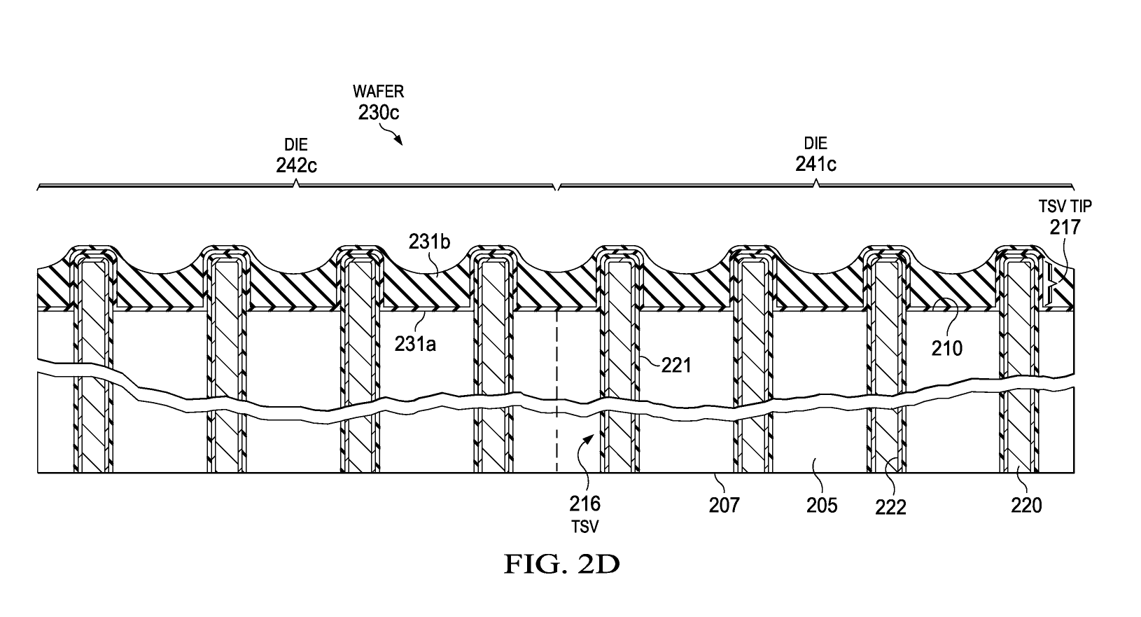

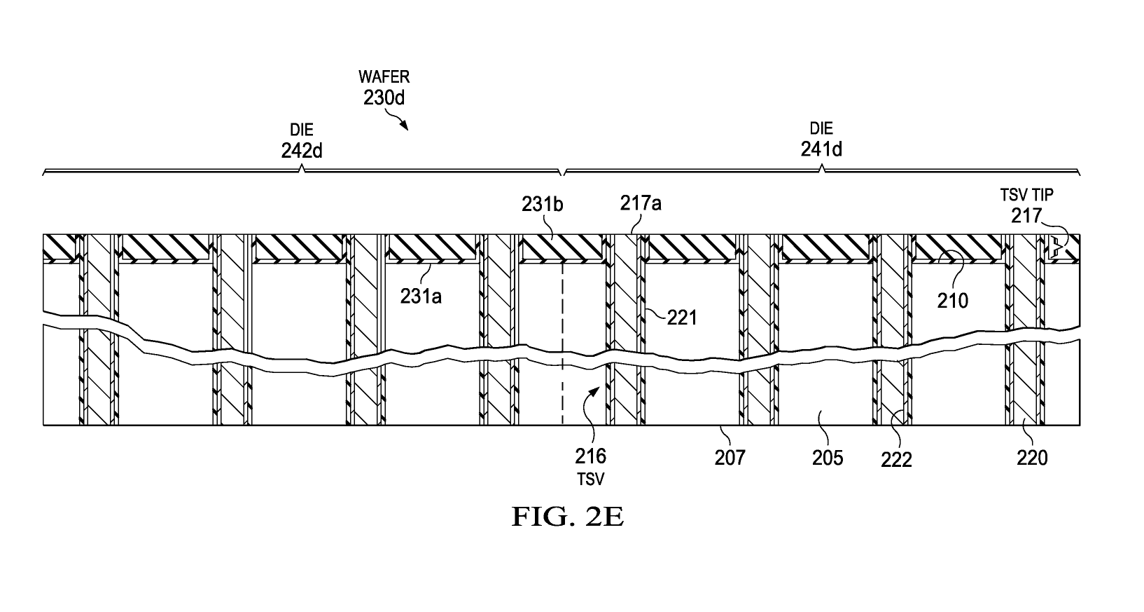

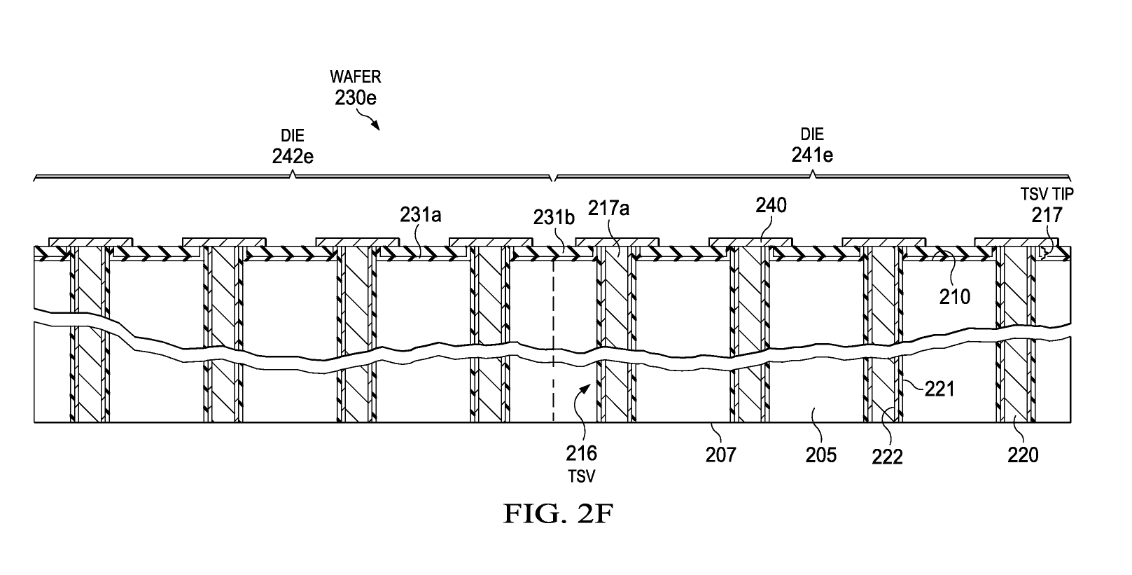

FIG. 2A shows a simplified cross sectional depiction of a wafer 230 comprising a plurality of die 241, 242 including a substrate 205 having a plurality of embedded vias 276 including a top side semiconductor surface 207 and bottom side surface 210 after bottom side wafer thinning, such as using a carrier wafer-based backgrinding process. For example, the wafer 230/substrate 205 may be thinned to a thickness of 60 μm to 80 μm from an initial (pre-thinning) thickness of about 500 μm to 775 μm. The distance between the distal end of the embedded vias 276 and the bottom side surface 210 after thinning may be about 8 μm±4 μm.

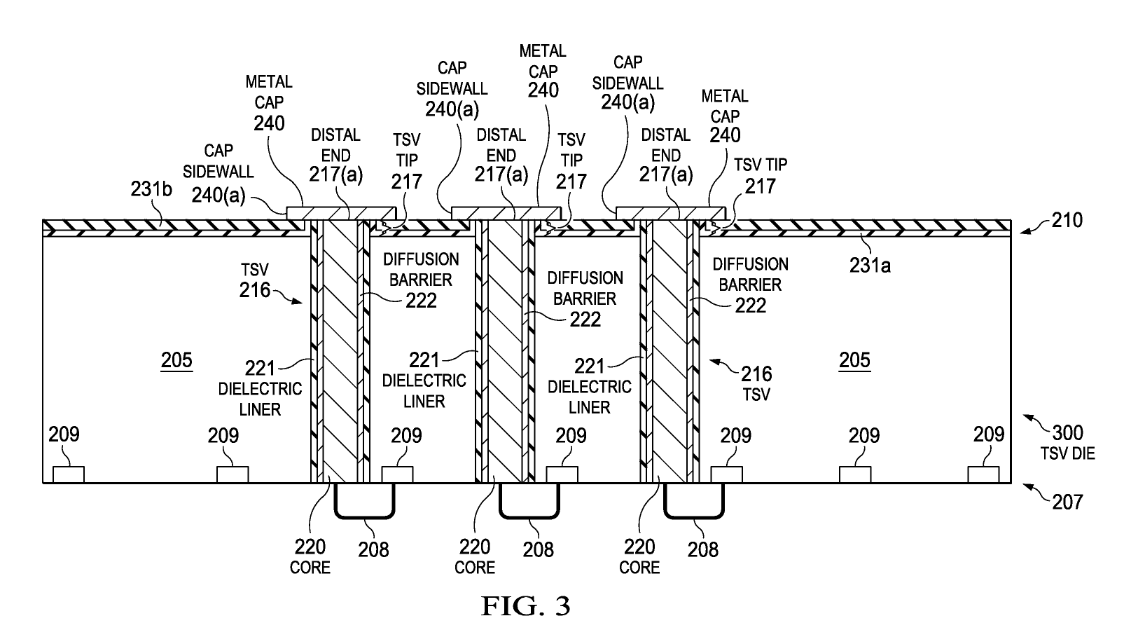

The top side semiconductor surface 207 includes active circuitry (see active circuitry 209 shown in FIG. 3). The embedded vias 276 are shown including a dielectric liner 221 (or dielectric sleeve) and diffusion barrier layer 222 with an inner metal core 220 within the diffusion barrier layer 222. The embedded vias 276 are generally coupled to the contact level or one of the BEOL metal layers (e.g., M1, M2, etc.) on the top side semiconductor surface 207. In one embodiment the embedded vias 276 have a circular cross section including a diameter≦12 μm, such as 3 μm to 10 μm in one particular embodiment.

The inner metal core 220 can comprise copper. Other electrically conductive materials can also be used for the inner metal core 220. The dielectric liner 221 can comprise materials such as silicon oxide, silicon nitride, phosphorus-doped silicate glass (PSG), silicon oxynitride, or certain chemical vapor deposited (CVD) polymers (e.g., parylene). The dielectric liner 221 is typically 0.2 μm to 3 μm thick.

In the case of copper and certain other metals for the inner metal core 220, to prevent escape of the metal into the surrounding semiconductor, a diffusion barrier layer 222, such as a refractory metal or a refractory metal nitride, is generally added which can be deposited on the dielectric liner 221. For example, diffusion barrier layer 222 can include materials comprising Ta, W, Mo, Ti, TiW, TiN, TaN, WN, TiSiN or TaSiN, which can be deposited by physical vapor deposition (PVD) or CVD. The diffusion barrier layer 222 is typically 100 Å to 500 Å thick.

FIG. 2B shows a simplified cross sectional depiction of the wafer 230 shown in FIG. 2A after substrate (e.g., silicon) etch, which can include wet and/or dry etching, to expose the TSVs 216 including forming TSV tips 217, now shown as wafer 230a and die 241a, 242a. TSVs 216 extend from the top side semiconductor surface 207 to the bottom side surface 210 and the TSV tips 217 protrude from the bottom side surface 210 of the substrate 205. In one embodiment a median length of the protruding TSV tips 217 measured from the bottom side surface 210 of the substrate is from 2 μm to 10 μm.

Step 102 comprises depositing a tip deformation protecting dielectric layer on the bottom side surface 210 of the substrate 205, wherein an elastic modulus of the tip deformation protecting dielectric layer is greater than (>) an elastic modulus of the electrically conductive filler material. The tip deformation protecting dielectric layer can be deposited directly on the bottom side surface 210 of the substrate 205. Generally, a second dielectric layer comprising a polymer is deposited on the tip deformation protecting dielectric layer.

FIG. 2C shows a simplified cross sectional depiction of the wafer 230a shown in FIG. 2B after depositing of a tip deformation protecting dielectric layer 231a directly on the bottom side surface 210 of the substrate 205 (step 102), now shown as wafer 230b and die 241b, 242b. Although the tip deformation protecting dielectric layer 231a is shown directly on the bottom side surface 210 of the substrate 205, in another embodiment, an inorganic dielectric layer generally 50 nm to 300 nm thick can be between the bottom side surface 210 of the substrate 205 and the tip deformation protecting dielectric layer 231a. The inorganic dielectric layer can comprise an oxynitride, nitride, or oxide, such as a PSG having a P content from 1 to 10 wt. % in one particular embodiment.

A disclosed tip deformation protecting layer 231a on the bottom side surface 210 of the substrate (e.g., wafer) resists subsequent TSV tip 217 deformation in the critical region where the TSV tip 217 protrudes from the bottom side surface 210 of the substrate 205 and helps prevent damage to the dielectric liner 221 in this region. The material and thickness for the tip deformation protecting layer 231a can be selected based on consideration of:

(i) prevention of the deformation of TSV tip 217 at the intersection (triple point) formed by the bottom side surface 210 of the substrate 205, the TSV tip deformation protecting layer 231a, and the dielectric liner 221;

(ii) the interfacial adhesion strength of the tip deformation protecting layer 231a-substrate interface to be greater than the yield strength of the electrically conductive filler material of the inner metal core 220 (e.g., copper);

(iii) tip deformation protecting layer 231a elastic modulus is greater than (>) elastic modulus of the electrically conductive filler material of the inner metal core 220, and

(iv) mechanical properties of the tip deformation protecting layer 231a. The compressive strength of the tip deformation protecting layer 231a should be such as to withstand the lateral stresses generated within the tip deformation protecting layer 231a, and the TSV tip 217 from the axial stress applied during TC bonding.

The tip deformation protecting dielectric layer 231a can comprise materials such as silicon nitride (SiN, although non-stoichiometric, generally referred to as SiN) or silicon oxynitride, which can both be deposited by chemical vapor deposition, such as low pressure chemical vapor deposition (LPCVD). The tip deformation protecting layer 231a can be 0.2 μm to 2 μm thick. Step 103 comprises depositing a second dielectric layer 231b comprising a polymer on the tip deformation protecting dielectric layer 231a. The polymer can comprise a variety of relatively high temperature tolerant (e.g., tolerant to at least 250° C. for a brief period) polymers such as benzocyclobutene (BCB), polybenzoxazole (PBO), parylene, or a polyimide (PI). The polymer forming step can comprise a spin-on process. Lamination may generally also be used. Some polymers may also be deposited by chemical vapor deposition (CVD), such as poly(p-xylylene) polymers (parylene).

FIG. 2D shows a simplified cross sectional depiction of the wafer 230b shown in FIG. 2C after forming (e.g., depositing) the second dielectric layer 231b comprising a polymer on the tip deformation protecting dielectric layer 231a on the bottom side surface 210 of the substrate, now shown as wafer 230c and die 241c, 242c. The deposited thickness of the second dielectric layer 231b may be 2 μm to 12 μm. Although not shown in FIG. 2D, in the case the deposited thickness of the second dielectric layer 231b is thicker than the protrusion length of TSV tips 217 from the bottom side surface 210 of the substrate, the second dielectric layer 231b can be subsequently thinned by wet and/or dry etch processing to reveal the TSV tips 217 prior to CMP processing (step 104 described below).

Step 104 comprises CMP to re-expose (reveal) the distal end of the TSV tips 217. FIG. 2E shows a cross sectional depiction showing the wafer 230c shown in FIG. 2D after re-exposing the distal end 217a of the TSV tips 217 (step 103), now shown as wafer 230d and die 241d, 242d. As shown in FIG. 2D, CMP reduces the length of the TSV tips 217.

Following CMP (step 104), a process loop can be added to provide metal caps on the distal end 217a of the TSV tips 217. FIG. 2F shows a cross sectional depiction showing the wafer 230d shown in FIG. 2D after plating the metal caps 240 on the distal end 217a of the TSV tips 217, now shown as wafer 230e and die 241e, 242e. Metal caps 240 include a metal different from the electrically conductive filler material of the inner metal core 220, such as nickel or nickel-gold. The method can also include physical vapor deposition (PVD) of barrier/seed films, such as TiW and Cu, that may be needed for electrolytic plating when the metal caps 240 comprise certain metals. Metal caps 240 can optionally be deposited by electroless or immersion plating techniques that avoid the need for the PVD films and the associated requisite patterning processes.

FIG. 3 is a simplified cross sectional depiction of an example TSV die 300 having TSVs 216 including protruding TSV tips 217 extending out from bottom side surface 210 of the substrate 205 and a dielectric stack including the second dielectric layer 231b on the tip deformation protecting dielectric layer 231a on the bottom side surface 210 of the substrate in the field regions between the TSV tips 217, according to an example embodiment. The TSV tips 217 are shown having metal caps 240 thereon. Although the metal cap 240 is shown (shaped) as an electrolytically plated metal cap, the metal cap 240 may also be plated electrolessly.

The dielectric stack (second dielectric layer 231b on tip deformation protecting layer 231a) can be seen to be substantially flush with respect to the top of the inner metal core 220 at the TSV distal tip end 217(a). As used herein, “substantially flush” refers to a thickness of the dielectric stack (231b on 231a) adjacent to the TSV 216 approximately equal to a length from the bottom side surface 210 to the distal tip end 217(a). The protruding TSV tips 217 are shown having an optional metal cap 240 on their distal tip ends 217(a). The sidewall of the metal cap 240 is shown as 240(a).

TSV die 300 comprises a substrate 205 including a top side semiconductor surface 207 including active circuitry 209 and a bottom side surface 210. The active circuitry 209 on TSV die 300 is configured to provide an IC circuit function, such as a logic function, for example. The connectors 208 shown depict the coupling between the TSVs 216 on the top side semiconductor surface 207 to the active circuitry 209. The connection provided by connectors 208 to the active circuitry 209 is optional, since the connection may simply pass through the substrate 205 without connecting to active circuitry 209, such as for a power supply connection.

The TSVs 216 comprise an outer dielectric sleeve (or dielectric liner) 221 and an inner metal core 220 comprising an electrically conductive filler material, and a diffusion barrier layer 222 between the dielectric sleeve 221 and the inner metal core 220. The TSVs 216 extend from the top side semiconductor surface 207 to protruding TSV tips 217 emerging from the bottom side surface 210 of substrate 205.

For example, in one particular embodiment the tip ends 217(a) of the TSV tips 217 can extend out about 5 μm from the bottom side surface 210 of TSV die 300, the metal caps 240 add about 5 μm in height to the TSV tips 217, and the dielectric stack (231b on 231a) total thickness is in the range from 0.5 μm to 3.5 μm.

The active circuitry 209 formed on the top side semiconductor surface 207 of the substrate 205 comprises circuit elements that may generally include transistors, diodes, capacitors, and resistors, as well as signal lines and other electrical conductors that interconnect the various circuit elements to provide an IC circuit function. As used herein “provide an IC circuit function” refers to circuit functions from ICs, that for example may include an application specific integrated circuit (ASIC), a digital signal processor, a radio frequency chip, a memory, a microcontroller and a system-on-a-chip or a combination thereof.

Disclosed embodiments can be integrated into a variety of assembly flows to form a variety of different semiconductor integrated circuit (IC) devices and related products. The assembly can comprise single semiconductor die or multiple semiconductor die, such as PoP configurations comprising a plurality of stacked semiconductor die. A variety of package substrates may be used. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. A through-substrate via (TSV) die, comprising:
a substrate having a top side semiconductor surface having active circuitry therein including a plurality of transistors functionally connected and a bottom side surface;
a plurality of TSVs which extend from said top side semiconductor surface to TSV tips which protrude from said bottom side surface and comprise an inner metal core comprising an electrically conductive filler material surrounded by a dielectric liner that forms an outer edge for said plurality of TSVs;
a tip deformation protecting layer comprising an inorganic dielectric material on said bottom side surface lateral to said TSV tips, wherein an elastic modulus of said inorganic dielectric material is greater than (>) an elastic modulus of said electrically conductive filler material, and
a second dielectric layer comprising a polymer on said tip deformation protecting layer.

2. The TSV die of claim 1, wherein said inorganic dielectric material comprises silicon nitride or silicon oxynitride.

3. The TSV die of claim 1, wherein said tip deformation protecting layer is 0.2 μm to 2 μm thick.

4. The TSV die of claim 1, wherein said inorganic dielectric material is directly on said bottom side surface lateral to said TSV tips.

5. The TSV die of claim 1, wherein said polymer comprises benzocyclobutene (BCB), polybenzoxazole (PBO), parylene, or a polyimide (PI).

6. The TSV die of claim 1, further comprising a diffusion barrier layer between said dielectric liner and said inner metal core.

7. The TSV die of claim 1, wherein said electrically conductive filler material comprises copper, further comprising metal caps on distal tip ends of said TSV tips including a metal different from said electrically conductive filler material.

8. A method of fabricating through-substrate via (TSV) die, comprising:
thinning from an initial bottom side of a substrate having a TSV die including a top side semiconductor surface including active circuitry therein comprising a plurality of transistors functionally connected attached to a carrier to reach a bottom side surface to expose a plurality of embedded filled vias to form a plurality of TSVs which extend from said top side semiconductor surface to TSV tips having exposed distal tip ends that protrude from said bottom side surface and comprise an inner metal core comprising an electrically conductive filler material surrounded by a dielectric liner that forms an outer edge for said plurality of TSVs;
depositing a tip deformation protecting layer comprising an inorganic dielectric material on said bottom side surface, wherein an elastic modulus of said inorganic dielectric material is greater than (>) an elastic modulus of said electrically conductive filler material;
forming a second dielectric layer comprising a polymer on said tip deformation protecting layer before chemical mechanical polishing (CMP), and
said CMP to reveal said distal tip ends of said TSV tips.

9. The method of claim 8, wherein said inorganic dielectric material comprises silicon nitride or silicon oxynitride.

10. The method of claim 8, wherein said tip deformation protecting layer is 0.2 μm to 2 μm thick.

11. The method of claim 8, wherein said inorganic dielectric material in said depositing is deposited directly on said bottom side surface lateral to said TSV tips.

12. The method of claim 8, wherein said polymer comprises benzocyclobutene (BCB), polybenzoxazole (PBO), parylene, or a polyimide (PI).

13. The method of claim 8, wherein said substrate is a silicon comprising wafer including a plurality of said TSV die.

14. The method of claim 8, wherein said electrically conductive filler material comprises copper, further comprising plating metal caps on said distal tip ends of said TSV tips including a metal different from said electrically conductive filler material.

15. A through-substrate via (TSV) die, comprising:
a substrate having a top side silicon surface having active circuitry therein including a plurality of transistors functionally connected and a bottom side surface;
a plurality of TSVs which extend from said top side silicon surface to TSV tips which protrude from said bottom side surface and comprise an inner metal core comprising copper surrounded by a dielectric liner that forms an outer edge for said plurality of TSVs, and a diffusion barrier layer between said dielectric liner and said inner metal core;
a tip deformation protecting layer comprising an inorganic dielectric material directly on said bottom side surface lateral to said TSV tips, wherein an elastic modulus of said inorganic dielectric material is greater than (>) an elastic modulus of said copper, and a second dielectric layer comprising a polymer on said tip deformation protecting layer.

16. The TSV die of claim 15, wherein said inorganic dielectric material comprises silicon nitride or silicon oxynitride, and wherein said tip deformation protecting layer is 0.2 μm to 2 μm thick.

17. The TSV die of claim 15, further comprising metal caps on distal tip ends of said TSV tips including a metal different from said copper.

18. The TSV die of claim 15, wherein said polymer comprises benzocyclobutene (BCB), polybenzoxazole (PBO), parylene, or a polyimide (PI).
